(19) United States
(12) Patent Application Publication
(10) Pub. No.: US 2009/0116187 A1
(43) Pub. Date: May 7, 2009

(54) OPACITY ENCLOSURE FOR FIPS 140-2

(75) Inventors: George Youzhi Yi, Fremont, CA (US); Lwin O. Tint, Newark, CA (US); Robert A. Loose, Cary, NC (US)

Correspondence Address: LAW OFFICE OF CHARLES E. KRUEGER, P.O. BOX 5607, WALNUT CREEK, CA, 94596-1607, US

(73) Assignee: CISCO TECHNOLOGY, INC., San Jose, CA (US)

(21) Appl. No.: 12/127,732

(22) Filed: May 27, 2008

Related U.S. Application Data
(60) Provisional application No. 60/985,963, filed on Nov. 6, 2007.

(51) Int. Cl. H05K 7/20

(52) U.S. Cl. 361/692

(57) ABSTRACT

In one embodiment, an opaque enclosure for an electronics module includes an inner barrier having downward-facing louvers for allowing air flow and a cover having vent holes. The vent holes and downward-facing louvers are oriented so that the interior of the electronics module is not visible through the vent holes of the cover.

### RELATED APPLICATIONS

This application claims priority from a provisional patent application entitled OPACITY ENCLOSURE FOR FIPS 140-2 filed on Nov. 6, 2007, Application No. 60/985,963, which is hereby incorporated by reference for all purposes.

### TECHNICAL FIELD

The present disclosure relates generally to dissipating heat from electronic modules while meeting government-required opacity standards.

### BACKGROUND OF THE INVENTION

Products sold to the government are required to meet the security requirement of FIPS 140 (Federal Information Processing Standards 140). In particular, FIPS 140-2 specifies the requirement that “the enclosure of the cryptographic module shall be opaque within the visible spectrum”. Many products evaluated by the Cryptographic Module Valuation Program (CMVP) fail due to a vague definition of opacity. The requirement that “the enclosure of the cryptographic module shall be opaque within the visible spectrum” is subjective and the pass/failure conclusions are largely determined by the evaluator's personal opinion. The enclosure will fail if any component or trace is visible through vents or openings of the enclosure.

Some existing products are designed with small vent holes or provided with vision obscuring screens or mesh. These methods reduce the airflow, which could cause heat dissipation problems. Further, reducing the size of the vent holes does not assure the a CMVP evaluator will pass the product. Other existing products have utilized a design including an external vision barrier which results in increased cost, fan speed, increased acoustic noise with reduced cooling efficiency.

### BRIEF DESCRIPTION OF THE DRAWINGS

FIG. 1 illustrates an example of an opaque enclosure of an electronic module;

FIG. 2 illustrates an example of an inner barrier of the opaque enclosure; and

FIG. 3 illustrates an example of an inner barrier having downward-facing louvers; and

FIGS. 4A and 4B illustrate an example embodiment where a cover is disposed over the inner barrier.

### DESCRIPTION OF EXAMPLE EMBODIMENTS

### Overview

A fully opaque enclosure for an electronic module having a base forming its bottom part includes an inner barrier positioned substantially perpendicular to the base and substantially along the periphery, with the inner barrier having openings to facilitate air flow and reduce thermal impedance. A cover encloses the module and the inner barrier, with the cover having a plurality of vent holes orientated so that the interior of the module is not visible through the vent holes.

The openings of the inner barrier and vent holes of the cover cooperate to reduce thermal impedance of the enclosure and to prevent any component or trace from being visible through vents or openings in the enclosure.

### Description

Reference will now be made in detail to various embodiments of the invention. Examples of these embodiments are illustrated in the accompanying drawings. While the invention will be described in conjunction with these embodiments, it will be understood that it is not intended to limit the invention to any embodiment. On the contrary, it is intended to cover alternatives, modifications, and equivalents as may be included within the spirit and scope of the invention as defined by the appended claims. In the following description, numerous specific details are set forth in order to provide a thorough understanding of the various embodiments. However, the present invention may be practiced without some or all of these specific details. In other instances, well known process operations have not been described in detail in order not to unnecessarily obscure the present invention.

Example embodiments of enclosures for modules having requirements including meeting the FIPS 140-2 will now be described. These example embodiments provide a complete opacity enclosure for such modules. An element of each of these example embodiments is an inner barrier that blocks vision from outside the module enclosure. Airflow passes through the openings in the inner barrier and exits from the vent holes in a top cover.

As is understood by persons having ordinary skill in the art, a key requirement of the design of any enclosure for an electronic system is the provision of adequate air flow to dissipate the heat generated by the electronic components in the system. If the heat is not dissipated then the system will either not function properly or be damaged.

The thermal impedance of the enclosure is a measure of the resistance of the enclosure to the outflow of heat generated by the electronic components. A common technique for reducing the thermal impedance is to include vent holes to allow air flow and heat dissipation. However, the use of vent holes results in a non-opaque enclosure.

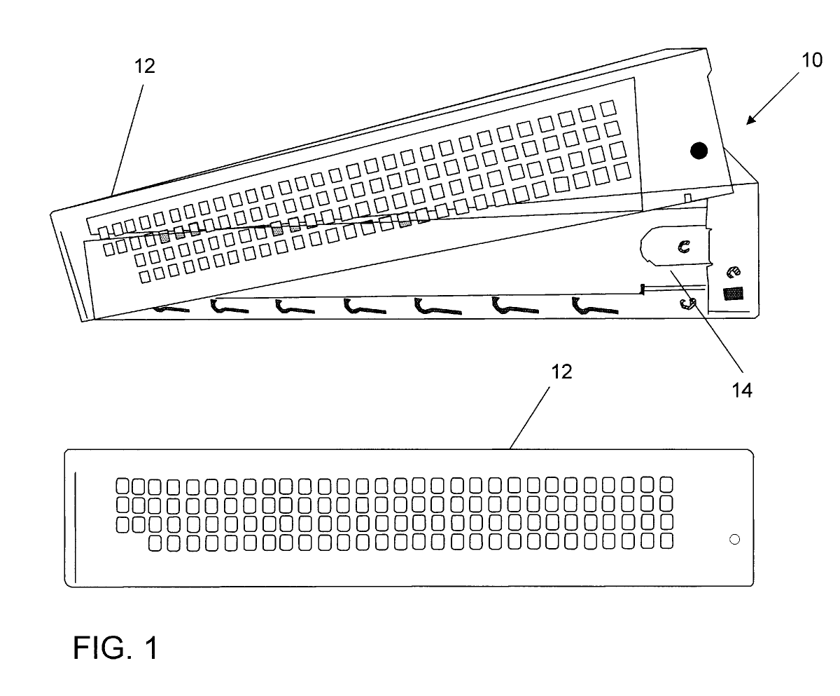

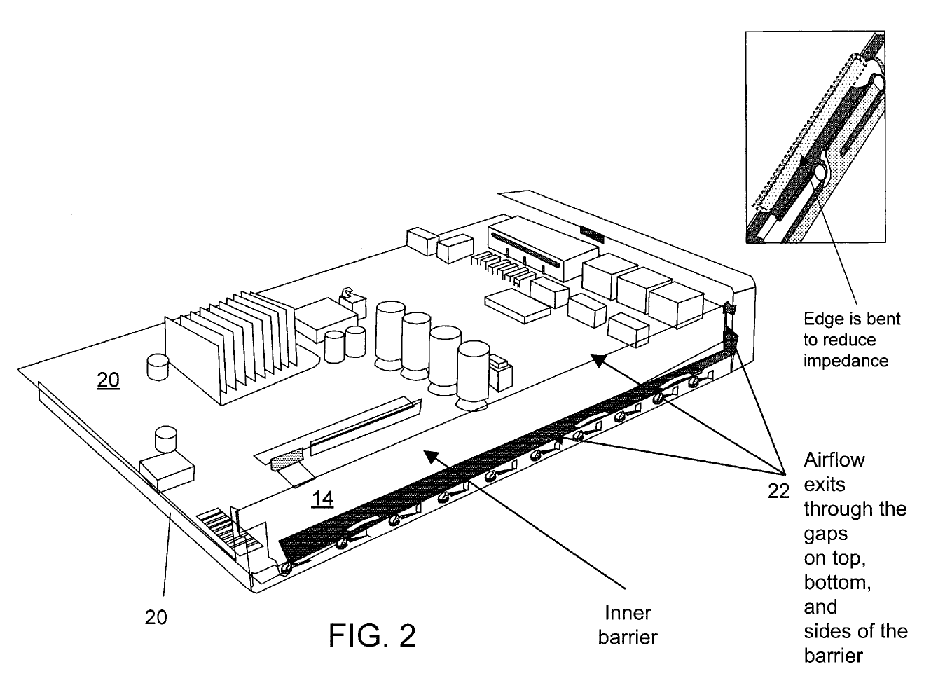

A first example embodiment will now be described with reference to FIGS. 1 and 2. In FIG. 1 the module enclosure 10 is a chassis having a sheet metal cover 12 including large sized vent holes to provide good air flow and a sheet metal inner vision barrier 14 configured so that components of the module are not visible through the vent holes of the cover 12.

FIG. 2 depicts an example of the inner barrier 14. The module includes a base 20 upon which the electronic components are mounted. The inner barrier 14, which is a solid plate formed from the sheet metal base, includes gaps 22 on the top, bottom, and sides that function as air flow exits. The gaps 22 are positioned so that the interior of the module is not visible through the vent holes of the cover 12.

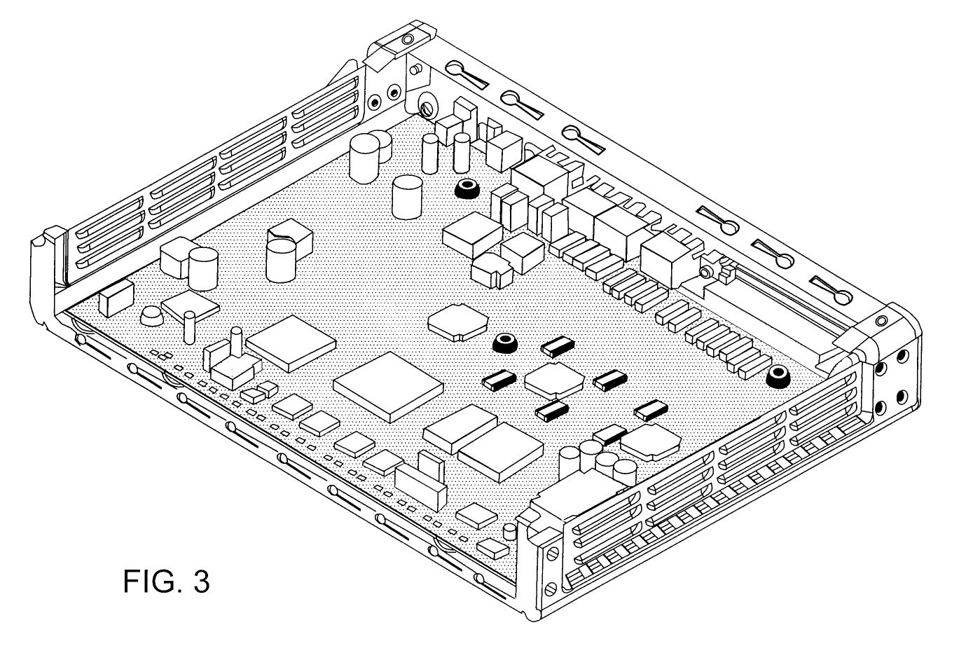

FIG. 3 depicts an alternate design of the interior barrier 14. The inner barrier includes downward-facing lovers 30 which increase air flow and lower thermal impedance. Because the louvers 30 face downward the interior of the module is not visible through the vent holes of the cover 12.

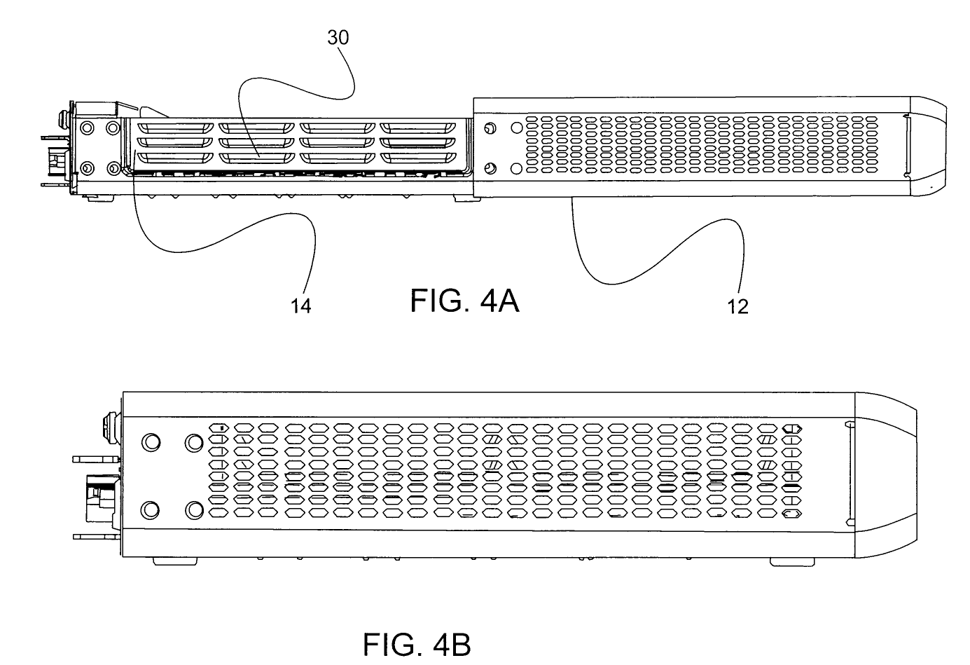

FIGS. 4A and 4B illustrate that when the cover 12 is slid over the base the vent holes of the cover 12 and downward-facing lovers 30 of the inner barrier 14 are oriented so that components are not visible through any of the ventilation holes of the cover 12.

An example non-opaque enclosure utilizes vent holes having dimensions of 0.085 inches×0.085 inches which is the largest vent hole size allowed by safety rules. The total vent hole area is 4.34 in². However, the components of the module are visible the vent holes

In the design depicted in FIG. 1, the use of the inner barrier 14 allows the use of larger vent holes in the cover 12 without violating safety rules. For example, in one embodiment square vent holes having dimensions of 0.17 inches×0.17 inches are utilized to substantially increase the total open area to 8.67 in². The larger vent holes comply with safety rules because of the presence of the inner barrier. Thus, in this embodiment the total area of the vent holes is about double the total area of the holes of the non-opaque enclosure described above while the thermal impedance is about the same. However, the downward-facing louvers prevent the components of the module from being visible through the vent holes.

The design of the various example embodiments does not increase either the enclosure size or the amount of air resistance. The example embodiments described have even lower thermal impedance than a non-opaque chassis of the same size. Further, the example embodiments are fabrication-friendly designs, needing no special tools or processes to produce. The example embodiments may be utilized with systems having forced convection or natural convection.

The inner barrier allows the use of larger ventilation openings to result in lower thermal impedances than standard modules that do not provide the required opacity.

The invention has now been described with reference to the example embodiments. Alternatives and substitutions will now be apparent to persons of skill in the art. For example, in the above embodiment square vent holes have been described; however, other shapes and patterns may be utilized as is understood by persons of ordinary skill. Accordingly, it is not intended to limit the invention except as provided by the appended claims.

What is claimed is:

1. An apparatus comprising:
a base forming the bottom part of an electronics module;
an inner barrier positioned substantially perpendicular to the base and substantially along the periphery, with the inner barrier having openings to facilitate air flow and reduce thermal impedance; and
a cover enclosing the electronics module and inner barrier, with the cover having a plurality of vent holes oriented so that the interior of the electronics module is not visible through the vent holes.

2. The apparatus of claim 1 with the inner barrier further comprising:
downward-facing louvers for increasing air flow.

3. The apparatus of claim 1 with the inner barrier further comprising:
bent edges for increasing airflow.

4. The apparatus of claim 1 with the inner barrier further comprising:
gaps on the bottoms and sides for increasing air flow.

5. The apparatus of claim 1 further comprising:
a natural convection heat dissipation system.

6. The apparatus of claim 1 further comprising:
a forced convection heat dissipation system.

7. The apparatus of claim 1 where:
the vents and openings are large enough to effectively dissipate heat generated by the electronics module.

8. An apparatus comprising:
a base;
a cover, adapted to fit over the base, having a plurality of vent holes for allowing heat to escape from an electronics module enclosed by the cover; and
a vision barrier configured to be positioned inside the cover, to conduct heat from the electronics module to vent holes of the cover, and to prevent the electronics module enclosed by the cover from being visible through the vent holes of the cover.

9. The apparatus of claim 8 with the vision barrier further comprising:
an inner barrier having openings to allow air flow with the openings disposed so that the electronics module is not visible through the vent holes of the cover.

10. The apparatus of claim 9 with the inner barrier further comprising:
downward-facing louvers for increasing air flow.

11. The apparatus of claim 9 with the inner barrier further comprising:
bent edges for increasing airflow.

12. The apparatus of claim 9 with the inner barrier further comprising:
gaps on the bottoms and sides for increasing air flow.

13. The apparatus of claim 8 further comprising:
a natural convection heat dissipation system.

14. The apparatus of claim 8 further comprising:
a forced convection heat dissipation system.

15. The apparatus of claim 8 where:
the vents and openings are large enough to effectively dissipate heat generated by the electronics module.
